(19) United States
(12) Patent Application Publication
(10) Pub. No.: US 2011/0075335 A1
(43) Pub. Date: Mar. 31, 2011

(54) BIAXIAL HINGE MECHANISM

(76) Inventor: Tetsuro Nagami, Tokyo (JP)

(21) Appl. No.: 12/995,862

(22) PCT Filed: Jun. 23, 2009
(86) PCT No.: PCT/JP2009/002851

§ 371 Date: Dec. 2, 2010

(30) Foreign Application Priority Data
Sep. 5, 2008 (JP) 2008228537

(51) Int. Cl. H05K 7/16

(52) U.S. Cl. 361/679.01

(57) ABSTRACT

A biaxial hinge mechanism is composed of a monitor opening and closing mechanism 200 for allowing a monitor 3 to open and close with respect to a first rotation center axis X, and a monitor rotating mechanism 100 for allowing the monitor 3, which is rotated in the open direction with respect to the first rotation center axis X, to rotate about a second rotation center axis Y orthogonal to the first rotation center axis X. The monitor rotating mechanism 100 further includes a sub-base 14 fixed to a base 21 of the monitor opening and closing mechanism 200; a cylindrical boss 11 of which one end is fixed to the monitor 3, and of which the other end is supported rotatably about the second axis Y by the sub-base 14; and a bush 34 of which one end is fixed to the base 21 of the monitor opening and closing mechanism 200 and which is inserted into the boss 11 from the other end side thereof to journal the boss 11.

### TECHNICAL FIELD

The present invention relates to a biaxial hinge mechanism for opening and closing a monitor to unfold and fold the monitor and for making a rotation (autorotation) to change the orientation of the monitor.

### BACKGROUND ART

Passenger cars in recent years include one having provided therein a monitor for a television, DVD, game, or the like, intended for a rear seat occupant. In a vehicle including three-row seats or opposed seats, the monitor is mounted on a ceiling of the vehicle. Preferably, such a monitor is arranged such that the orientation of the screen thereof can be changed according to a seating position of the occupant, that is, how the occupant is seating facing forward or backward, in a reclining position, or the like. Further, there arises such a request not only in a vehicle but also in a system including a monitor.

FIG. 7 shows a structure of a conventional biaxial hinge that opens and closes a monitor to unfold and fold the monitor, and rotates the monitor to change the orientation of the monitor. FIG. 7 is a front view illustrating the state where the monitor is attached to the conventional biaxial hinge. The biaxial hinge is composed of a monitor rotating mechanism 100 for allowing a monitor 3 to rotate (autorotate) and a monitor opening and closing mechanism 200 for opening and closing the monitor 3. The monitor opening and closing mechanism 200 allows the monitor 3 to rotate together with the monitor rotating mechanism 100 about a first rotation center axis (hereinafter referred to as a “first axis”) X, and the monitor rotating mechanism 100 allows the monitor 3 to rotate about a second rotation center axis (hereinafter, referred to as a “second axis”) Y.

FIG. 8 is an exploded perspective view of the monitor rotating mechanism 100 of the conventional biaxial hinge as shown in FIG. 7, and FIG. 9A is a sectional view of the monitor rotating mechanism 100. A cylindrical boss 11 using the second axis Y as a central axis is provided on one face of the monitor 3. The boss 11 has formed at the end thereof on the opposite side from the monitor 3, D-cut sections 11a which are formed by flattening a portion of the outer peripheral face thereof, and a peripheral groove 11c which is formed by reducing in diameter the front end thereof. Further, a holding section 11b projecting from the outer peripheral face is formed therearound on the upper side of the D-cut sections 11a.

The boss 11 is passed therethrough by a presser plate 12 and a leaf spring 13 having a ring shape, a sub-base 14, a leaf spring 15 and a presser plate 16 also having a ring shape in this order. By crimping or caulking a fringe of the peripheral groove 11c of the boss 11 to form a crimped section 11d, the boss 11 is fixed to the sub-base 14. The sub-base 14 is secured to a base 21 of the monitor opening and closing mechanism 200 with screws 17.

Around the inner peripheries of holes formed through the presser plates 12, 16, and the leaf springs 13, 15 are formed straight line sections 12a, 13a, 15a, and 16a for fitting with the D-cut sections 11a of the boss 11. The D-cut sections 11a fit in the straight line sections 12a, 13a, 15a, and 16a, thus rotating the presser plates 12, 16, and the leaf springs 13, 15 together with the boss 11 when the boss 11 is rotated. On the other hand, since a hole 14a bored through the sub-base 14 does not have a straight line section provided around the inner periphery thereof, the sub-base 14 is not rotated even when the boss 11 is rotated.

The presser plate 16 is formed so as to have an inner diameter that fits in the peripheral groove 11c, and the presser plate 16 fits in the peripheral groove 11c, thus restraining the presser plate from moving to the upside. Furthermore, the presser plate 16 is fixed to the peripheral groove 11c, thus determining a holding width H (FIG. 9A) which is formed by the presser plate 16 and the holding section 11b. In the portion of the holding width H are attached the presser plate 12, the leaf spring 13, the sub-base 14, and the leaf spring 15, and those components are sandwiched in the vertical direction by the holding section 11b and the presser plate 16.

Engaging convexities 13b, 15b for engaging with engaging holes 14b of the sub-base 14 on the faces on the sub-base 14 side of the leaf springs 13, 15 are provided, respectively, and the engaging convexities 13b, 15b are pressed against the sub-base 14 by the elastic force of the leaf springs 13, 15, respectively. The engaging convexities 13b, 15b rotates while sliding on the sub-base 14 with the convexities pressed against the sub-base, and engage in the engaging holes 14b, thus positioning the monitor 3 at a predetermined angle with respect to the sub-base 14. Otherwise, when the engaging convexities 13b, 15b are in the positions where the convexities do not engage in the engaging holes 14b, the leaf springs 13, 15 are flexed by the height of the engaging convexities 13b, 15b. To secure a clearance required for the boss 11 to rotate with respect to the sub-base 14, the holding width H is adjusted to provide a clearance I each between the sub-base 14 and the leaf springs 13, 15 located on both sides of the sub-base. It is to be noted that the clearances I are not higher than the height to which the engaging convexities 13b, 15b project.

Therefore, since the monitor 3 can autorotate about the second axis Y with respect to the sub-base 14 using the boss 11, and further the monitor is resiliently pressed against the sub-base 14 by the leaf springs 13, 15, the monitor has suitable sliding resistance, and can autorotate requiring a suitable torque.

Moreover, the hinge device disclosed, e.g., in Patent Document 1 is arranged by passing a hinge main body through a cylindrical section provided across each end of two casings to rotatably connect the two casings to each other. The hinge main body has provided at the tip thereof, an engaging section having resilience, and the engaging section is arranged to resiliently engage with the cylindrical section.

### PRIOR ART DOCUMENTS

### Patent Documents

Patent Document 1: JP-A-2005-249067

### SUMMARY OF THE INVENTION

Since the conventional hinge mechanism is arranged as described above, there is a problem such that in the biaxial hinge mechanism shown in FIG. 7 to FIG. 9A, the leaf springs 13, 15 are flexed by vibrations within the inclination of the boss 11 brought about by the clearances I, which causes the chatter of the monitor rotating mechanism 100. FIG. 9B is a sectional view showing a state of the chatter when vibrations are transmitted to the monitor rotating mechanism 100 of the conventional biaxial hinge as shown in FIG. 9A. Since the monitor rotating mechanism 100 is provided with the only one hinge connection section which is parallel to the second axis Y, the chatter of the boss 11 caused in the clearances I of the monitor rotating mechanism 100 directly brings about the swing J of the monitor 3. Since the resilient leaf springs 13, 15 are flexed by transmission of vibrations, the inclination at the bottom of the boss 11 owing to the clearances I can cause the large swing J.

Further, in the conventional type hinge mechanism as disclosed in Patent Document 1, since the engaging section resiliently presses both the casings, the casings can be prevented from chattering in the direction of the hinge main body axis; however, the casings cannot be prevented from being flexed in the direction orthogonal to the axis of the engaging section. Therefore, there is a problem such that when vibrations are transmitted to the casings, the engaging section can be flexed to thus cause chatter.

Furthermore, when the aforementioned conventional hinge mechanism is applied to a monitor apparatus mounted in a vehicle, vibrations during operation causes chatter in the hinge mechanism to thus swing the monitor; consequently, there is a problem such that it becomes difficult to see the image thereof.

The present invention has been made to solve the above-mentioned problems, and an object of the present invention is to prevent a monitor rotating mechanism from being chattered by vibrations to restrain a monitor from being swung.

The biaxial hinge mechanism according to the present invention is composed of a monitor opening and closing mechanism for allowing a monitor to open and close with respect to a first rotation center axis, and a monitor rotating mechanism for allowing the monitor which is rotated in the open direction with respect to the first rotation center axis to rotate with respect to a second rotation center axis orthogonal to the first rotation center axis, and the biaxial hinge mechanism is arranged such that the monitor rotating mechanism includes a sub-base fixed to a base of the monitor opening and closing mechanism; a cylindrical boss of which one end is fixed to the monitor, and of which the other end is supported rotatably about the second rotation center axis by the sub-base; and a bush of which one end is fixed to the base of the monitor opening and closing mechanism and which is inserted into the boss from the other end side thereof to journal the boss.

According to the present invention, the bush fixed to the base is arranged so as to be inserted into the boss, which is rotatably supported by the sub-base, to journal the boss. Thus, the rigidity of the monitor rotating mechanism is improved, thus preventing the chatter caused by vibrations. As a result, the monitor 3 can be restrained from being swung.

### BRIEF DESCRIPTION OF THE DRAWINGS

FIG. 1A is a perspective view showing an operation of a monitor to which a biaxial hinge mechanism in accordance with the first embodiment of the present invention is applied with the monitor closed.

FIG. 1B is a schematic sectional view of the state shown in FIG. 1A.

FIG. 1C is a perspective view showing an operation of the monitor to which the biaxial hinge mechanism in accordance with the first embodiment of the present invention is applied with the monitor opened 120 degrees.

FIG. 1D is a perspective view showing an operation of the monitor to which the biaxial hinge mechanism in accordance with the first embodiment of the present invention is applied with the monitor opened 90 degrees.

FIG. 1E is a perspective view showing an operation of the monitor to which the biaxial hinge mechanism in accordance with the first embodiment of the present invention is applied with the monitor reversed from the state shown in FIG. 1C.

FIG. 1F is a perspective view showing an operation of the monitor to which the biaxial hinge mechanism in accordance with the first embodiment of the present invention is applied with the reversed monitor rotated 30 degrees from the state shown in FIG. 1E.

FIG. 1G is a perspective view showing an operation of the monitor to which the biaxial hinge mechanism in accordance with the first embodiment of the present invention is applied with the reversed monitor housed.

FIG. 2A is a front view of the biaxial hinge mechanism in accordance with the first embodiment of the present invention.

FIG. 2B is a perspective view of the biaxial hinge mechanism in accordance with the first embodiment of the present invention.

FIG. 3 is a perspective view of the biaxial hinge mechanism in accordance with the first embodiment of the present invention with a monitor rotating mechanism and a monitor opening and closing mechanism both disassembled.

FIG. 4 is a disassembled perspective view showing the monitor rotating mechanism of the biaxial hinge mechanism in accordance with the first embodiment of the present invention.

FIG. 5A is a sectional view of the monitor rotating mechanism of the biaxial hinge mechanism in accordance with the first embodiment of the present invention, taken along the line M-M in FIG. 2B.

FIG. 5B is a sectional view of the monitor rotating mechanism of the biaxial hinge mechanism in accordance with the first embodiment of the present invention, taken along the line N-N in FIG. 2B.

FIG. 6 is an explanatory view showing an operation of the monitor rotating mechanism of the biaxial hinge mechanism in accordance with the first embodiment of the present invention.

FIG. 7 is a front view showing a state where a monitor is attached to a conventional biaxial hinge.

FIG. 8 is a disassembled perspective view showing a monitor rotating mechanism of the conventional biaxial hinge.

FIG. 9A is a sectional view showing the monitor rotating mechanism of the conventional biaxial hinge.

FIG. 9B is a sectional view showing a state where vibrations have been transmitted to the monitor rotating mechanism of the conventional biaxial hinge.

### BEST MODE FOR CARRYING OUT THE INVENTION

Embodiments of the present invention will now be described with reference to the accompanying drawings in order to explain the present invention in more detail.

### First Embodiment

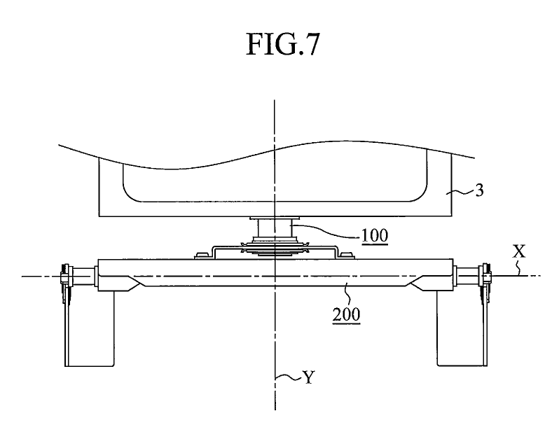

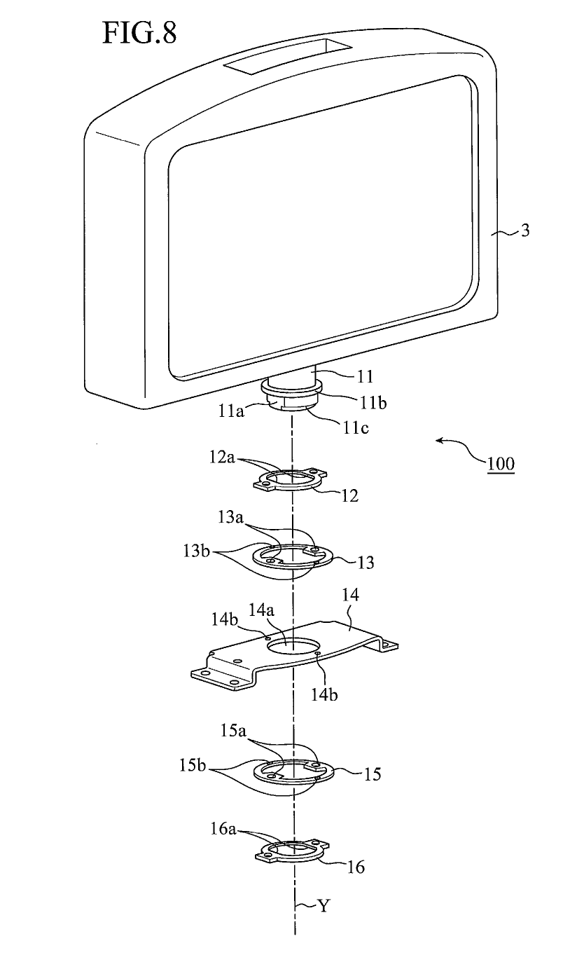

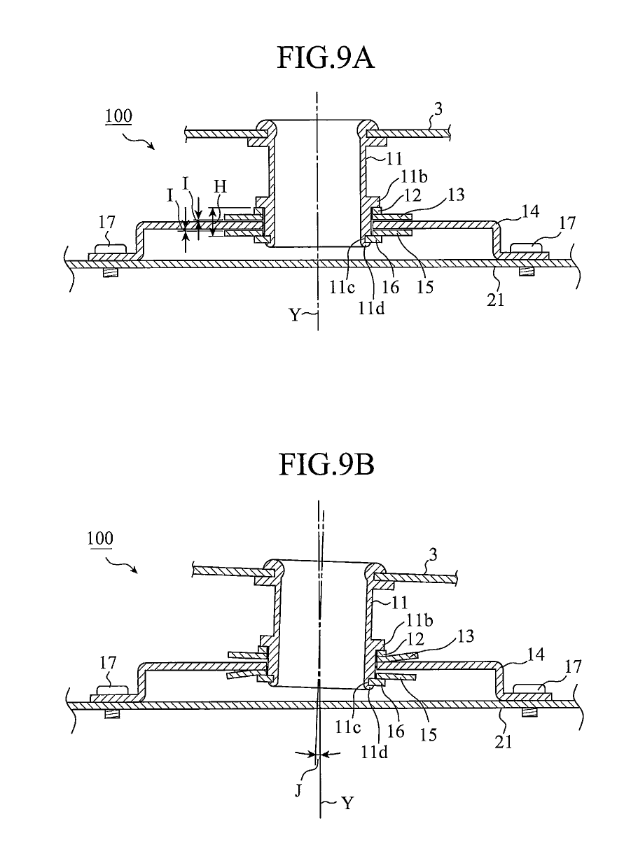

A first embodiment of the present invention will next be described with reference to the drawings in detail. It should be appreciated that in the following explanation of the embodiment, parts which are the same as or equivalent to the constituent elements in the conventional art (FIG. 7 to FIG. 9B) previously explained are designated by similar numerals, and these explanations will be omitted.

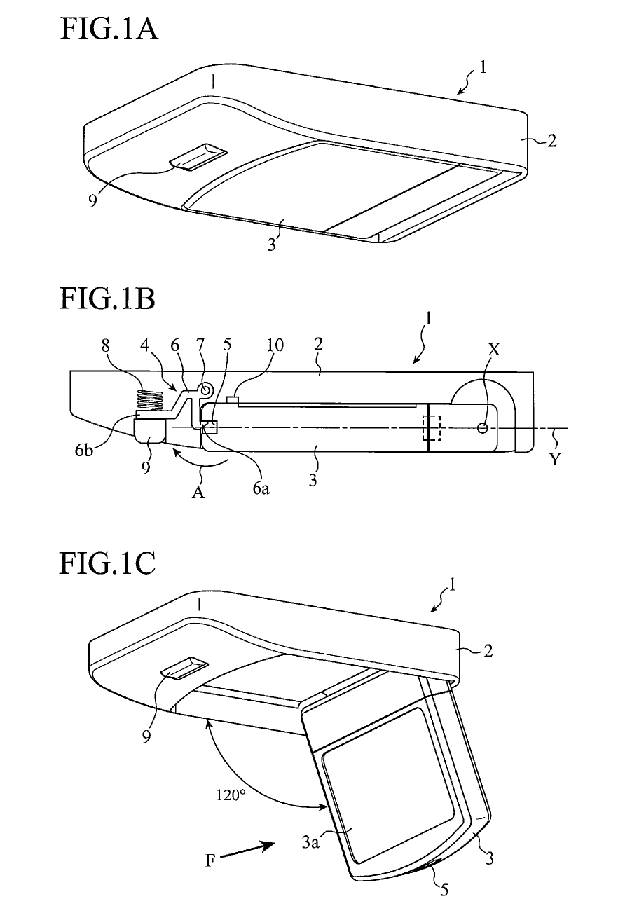

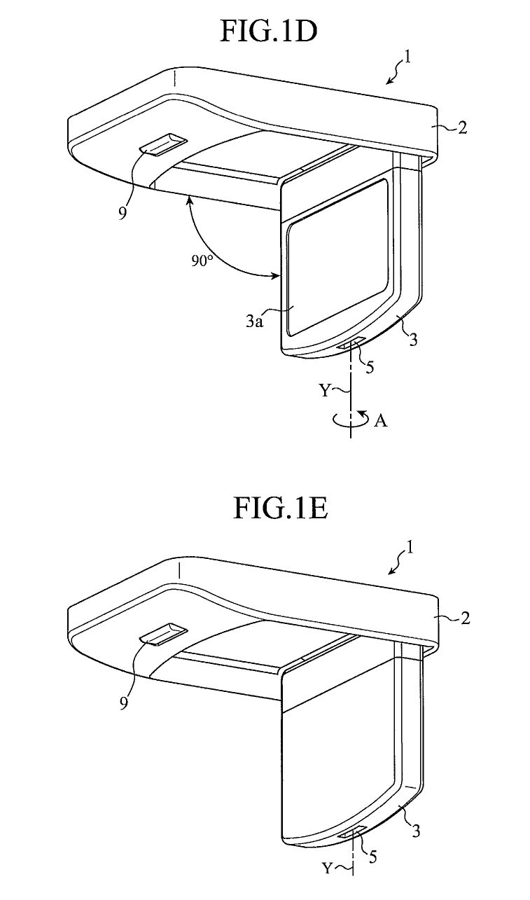

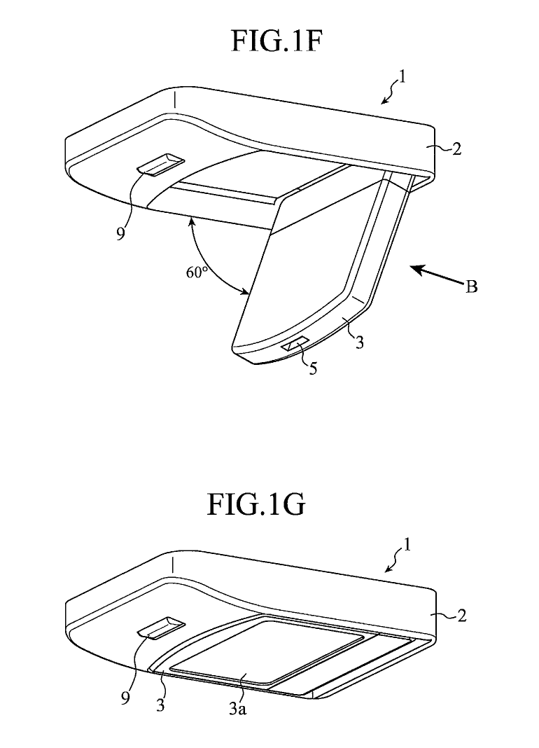

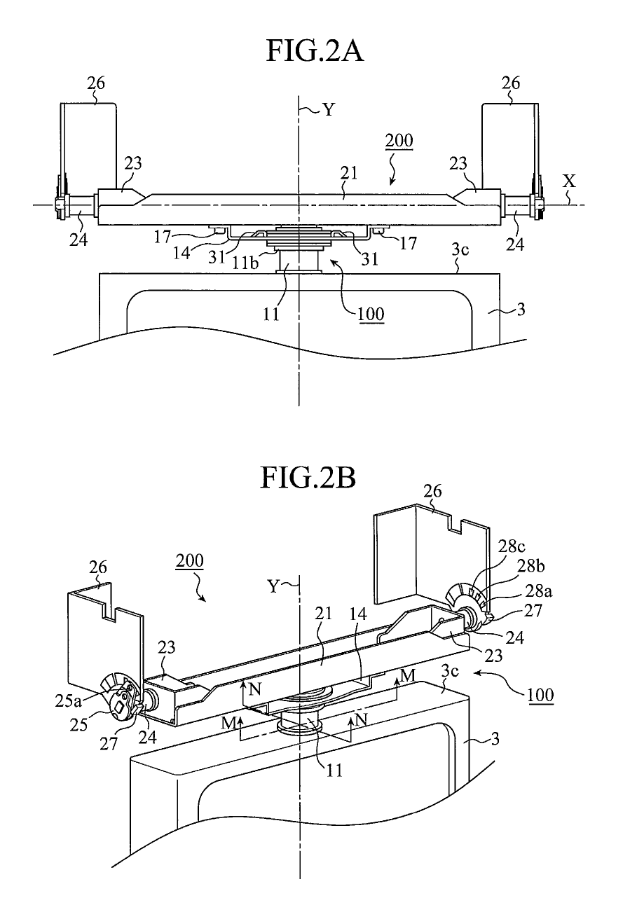

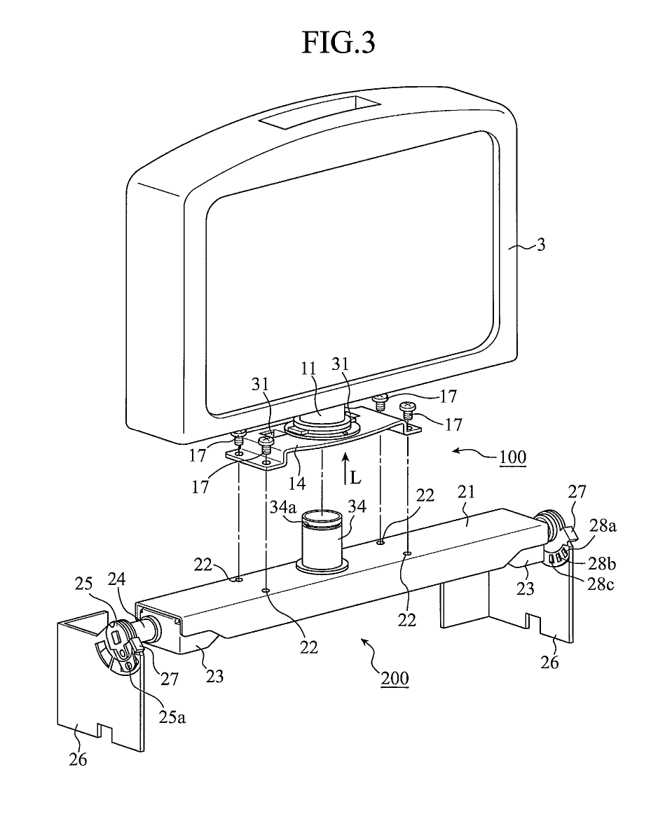

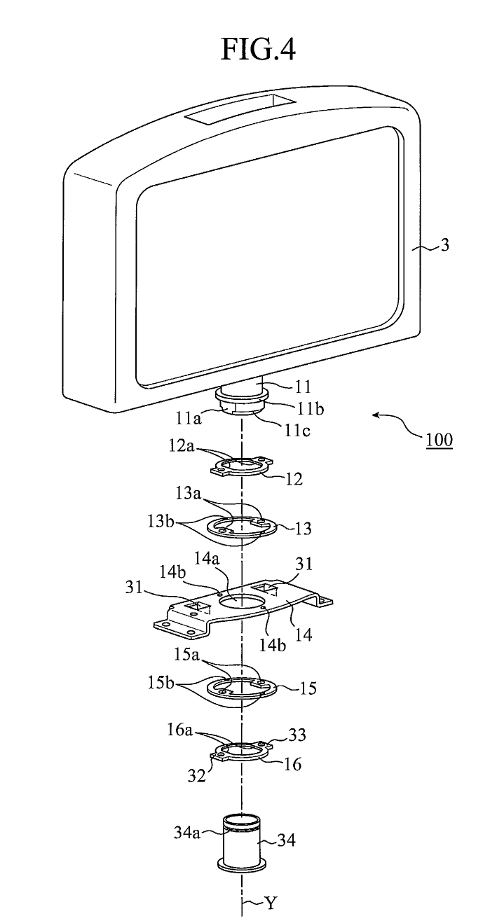

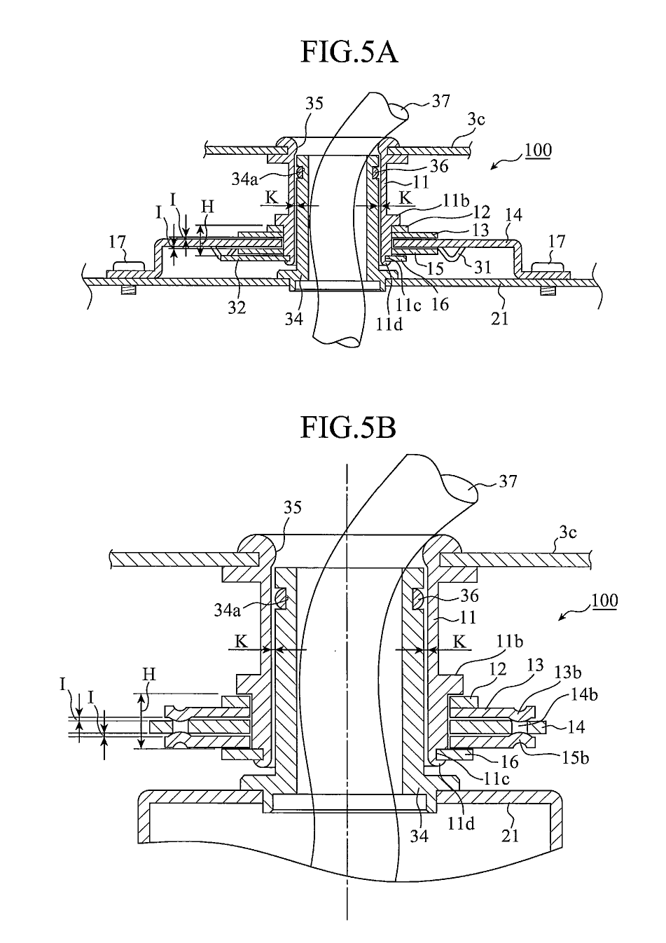

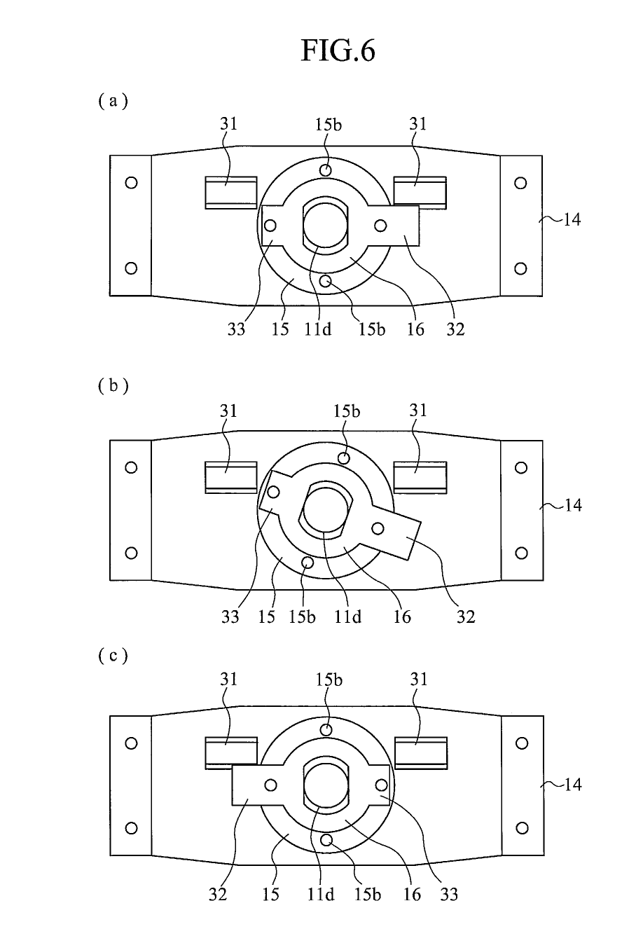

In the first embodiment, a biaxial hinge mechanism according to the present invention is applied to a monitor apparatus mounted on a ceiling of the interior of a vehicle. FIG. 1A to FIG. 1G are views showing a series of opening and closing, and autorotating operations of a monitor apparatus including a biaxial hinge mechanism in accordance with the first embodiment. FIG. 2A is a front view showing the biaxial hinge mechanism in accordance with the first embodiment to be employed in the monitor apparatus, and FIG. 2B is a perspective view of the biaxial hinge mechanism. FIG. 3 is a perspective view of the biaxial hinge mechanism in accordance with the first embodiment with a monitor rotating mechanism 100 and a monitor opening and closing mechanism 200 both disassembled, and FIG. 4 is a disassembled perspective view of the monitor rotating mechanism 100. FIG. 5A is a sectional view of the monitor rotating mechanism 100, taken along the line M-M in FIG. 2B, and FIG. 5B is a sectional view of the mechanism, taken along the line N-N in FIG. 2B. FIG. 6 is an explanatory view showing an operation of the monitor rotating mechanism 100, viewed from the direction L as shown in FIG. 3.

As shown in FIG. 1A to FIG. 1G, a monitor apparatus 1 consists of a monitor housing case 2 serving as a monitor housing section mounted on a ceiling of a vehicle and a monitor 3 that can be rotated (opened and closed) to be unfolded and folded with respect to the monitor housing case 2. A screen 3a is provided on one face of the monitor 3. The monitor 3 is rotated about a first axis X provided at one end portion thereof to be opened with respect to the monitor housing case 2, as shown in FIG. 1C, for instance. In the state where the monitor is opened 90 degrees with respect to the monitor housing case 2 as shown in FIG. 1D, the monitor 3 is reversed as shown in FIG. 1E when rotated 180 degrees about a second axis Y that is orthogonal to the first axis X and parallel to the screen 3a of the monitor 3. Further, the monitor 3 can be housed in the monitor housing case 2 as shown in FIG. 1G even in the reversed state. It is to be noted that in the following explanations, regardless of the angle about the first axis X, the state where the monitor 3 is in a state prior to the rotation of the monitor about the second axis Y (FIG. 1A to FIG. 1D) is referred to as a normal state, and the state where the monitor is rotated 180 degrees about the second axis Y to be reversed (FIG. 1E to FIG. 1G) is referred to as a reversion state or reversed state regardless of the angle to which the monitor is opened about the first axis X.

A lock mechanism 4 for locking or unlocking the monitor 3 to or from the monitor housing case 2 is provided between the end portion of the monitor 3 and the monitor housing case 2. A lock hole 5 serving as a lock member on one side of the lock mechanism 4 is formed in the middle of the end face on the tip side of the monitor 3. As shown in FIG. 1B, the lock hole 5 is provided on the second axis Y that is orthogonal to the first shaft X and passes through the center of the monitor 3 in the directions of the width and thickness thereof. On the side of the monitor housing case 2, a lock pawl member 6 working as a lock member on the other side thereof and having a pawl 6a that can engage and disengage with the lock hole 5 is provided rotatably through a shaft 7. The lock pawl member 6 has an operating section 6b provided on the opposite side thereof from the pawl 6a with respect to the shaft 7, and a spring force for pushing the pawl 6a into the lock hole 5 by a spring 8 is imparted to the operating section 6b. The operating section 6b has a button 9 provided on the opposite side thereof from the spring 8, and the button 9 is exposed from the surface of the monitor housing case 2. By pushing the button 9, the lock pawl member 6 is rotated to disengage the pawl 6a from the lock hole 5, and thereby the monitor 3 is opened downwardly about the first axis X. Further, when the monitor 3 is pushed into the monitor housing case 2, the monitor 3 enters the monitor housing case 2 while rotating the pawl 6a and the lock pawl member 6 against the spring force of the spring 8; when the lock hole 5 comes the position of the pawl 6a, the pawl 6a enters the lock hole 5 to lock the monitor 3. The pawl 6a has an incline provided at the tip thereof to be easily rotatable when pushed by the monitor 3.

In this context, the monitor housing case 2 has a rubber cushion 10 provided in a portion thereof against which the face (the portion in the front face of the monitor except the portion where the screen 3a is provided, and the back face 3b thereof) of the monitor 3 abuts. When the monitor 3 is housed therein, the face of the monitor 3 and the rubber cushion 10 are arranged to be in contact with each other, or keep a certain distance therebetween. Upon housing of the monitor 3, the rubber cushion 10 works as a buffer when the monitor 3 is pressed in the monitor housing case 2, and also prevents the monitor 3 housed therein from generating abnormal noise because of vibrations and being damaged thereby.

One example of the operation of the monitor apparatus 1 will be discussed with reference to FIG. 1A to FIG. 1G. FIG. 1A and FIG. 1B illustrate the state where the monitor 3 is housed in the monitor housing case 2. Under such a condition, the button 9 is pushed to disengage the pawl 6a of the lock pawl member 6 from the lock hole 5, and the monitor 3 is rotated about the first axis X by the self-weight thereof to be opened. FIG. 1C shows the state where the monitor 3 is opened and rotated to the position where the screen 3a is suitable for a viewing (and listening) from the direction F (the position where the monitor is rotated 120 degrees from the closed state). Some positions suitable for the viewing are arranged to be selectable according to occupant's seating conditions. FIG. 1D illustrates the state where the monitor 3 is rotated 90 degrees with respect to the closed position. The monitor 3 is rotated (autorotated) about the second axis Y with the state as a reference position. FIG. 1E illustrates the state where the monitor 3 autorotates through 180 degrees with respect to the state as shown in FIG. 1D. The monitor 3 can be positioned in a predetermined viewing position when rotated about the first axis X in the reversed state thereof. FIG. 1F shows the state where the monitor is rotated a predetermined angle (60 degrees with respect to the closed position) from the reversed state as shown in FIG. 1E to be positioned in a position suitable for a viewing from the direction B. Specifically, for example, this is the state where the position of the screen 3a is changed from the viewing position (FIG. 1C) for an occupant facing forwardly to the viewing position for an occupant facing backwardly in a vehicle room. Furthermore, FIG. 1G shows the state where the monitor 3 in the reversed state is housed in the monitor housing case 2 as it stands. The screen 3a is in a state housed in the ceiling, and this state provides a comfortable viewing, for example, when a seat is set in a reclining position by an occupant.

Referring to FIG. 2A to FIG. 5B, the monitor rotating mechanism 100 of the biaxial hinge mechanism that achieves the above-described autorotating operation of the monitor 3 about the second axis Y will next be discussed. The monitor 3 has a flat rectangular shape, and has the screen 3a provided on one face thereof as mentioned above. A cylindrical boss 11 using the second axis Y as a central axis is crimped to the central portion of a top face 3c of the monitor 3. On the other hand, a cylindrical rigid bush 34 having an outer diameter smaller than the inner diameter of the boss 11 by the dimension of a fit is secured to a base 21 of the monitor opening and closing mechanism 200. As illustrated in FIG. 3, the bush 34 is inserted in the boss 11, and a sub-base 14 united with the boss 11 is fastened to tapped holes 22 of the base 21 with screws 17, thus connecting the monitor rotating mechanism 100 with the monitor opening and closing mechanism 200. As shown in FIG. 5A and FIG. 5B, the bush 34 is arranged to have a length in the direction of the second axis Y extending partway along the height of the boss 11. Even if burrs or swellings are produced to form a swelling portion 35 upon crimping the boss 11 to the top face 3c, when the bush 34 is arranged to have the length in the direction of the second shaft Y extending partway along the height of the boss, that is, have the dimension not abutting against the swelling portion 35, the insertion of the bush 34 into the boss 11 can be completed; thus, there are no cases where the sub-base 14 is fixed to the base 21 in an incomplete insertion position. As a result, the rotational performance of the boss 11 to the bush 34 can be stabilized.

Moreover, a clearance K formed between the inner peripheral face of the boss 11 and the outer peripheral face of the bush 34 is slightly the dimension of a fit. For this reason, even if vibrations are transmitted to the biaxial hinge mechanism, the boss 11 is controlled on the level to be inclined with respect to the bush 34 within the range of the clearance K; thus, the chatter by flexing of leaf springs 13, 15 in a clearance I can be prevented. Consequently, the monitor 3 is not greatly swung in the direction orthogonal to the second axis Y. Further, the bush 34 is formed in a hollow through which a wiring member 37 such as a flexible printed board is passed. The wiring member 37 connects the monitor 3 with a main board (not shown) on the side of the monitor housing case 2 to send and receive electric signals. Furthermore, a groove 34a is provided along the outer peripheral face of the bush 34 near to the monitor 3, and an O-ring (a viscoelastic member) 36 is fit in the groove 34a. The O-ring 36 serves as a buffer when vibrations are transmitted to the biaxial hinge mechanism to prevent the generation of the collision noise of the boss 11 with the bush 34.

Two stoppers 31 for restraining the monitor 3 from further rotation by abutting against an abutting section 32 on the side of a presser plate 16 are prepared protrudingly downward on the surface of the sub-base 14. Further, the abutting section 32 and a protrusion 33 projecting outwardly in a radial direction are provided in the presser plate 16. The abutting section 32 is formed with a length to abut against the stopper 31 of the sub-base 14, while the protrusion 33 is formed with a length shorter than that of the abutting section 32 so as not to abut against the stopper 31.

Referring to FIG. 6, the autorotating operation of the monitor rotating mechanism 100 will next be described. FIG. 6 is a figure viewed from the back of the sub-base 14, and the drawing of the monitor 3 connected to the monitor rotating mechanism 100 will be omitted.

The position of the abutting section 32 shown in FIG. 6(a) is defined as “a reference position.” When the monitor 3 is in the reference position, the monitor is in a normal position. As shown in FIG. 6(a), the abutting section 32 of the presser plate 16 is formed at the position where the abutting section abuts against the stopper 31 or at the position where a slight clearance exists therebetween when engaging convexities 13b, 15b of the leaf springs 13, 15 engage with engaging holes 14b of the sub-base 14. Therefore, when the monitor 3 is autorotated from the reference position as shown in FIG. 6(a), the boss 11 is rotated together with the monitor 3 while journaled by the bush 34, and further, the abutting section 32 of the presser plate 16 fitting in the boss 11 is also rotated. At that time, since the protrusion 33 is shorter than the abutting section 32 in the radial length, no protrusion abuts against the stopper 31 (FIG. 6(b)). When the abutting section 32 is rotated 180 degrees from the reference position, that is, to the position shown in FIG. 6(c), the engaging convexities 13b, 15b are engaged in the engaging holes 14b to be positioned, and even if the abutting section is pushed in an attempt to be further rotated in the same direction, the abutting section 32 is arranged not to be further rotated since the abutting section abuts against the stopper 31. At that time, the monitor 3 autorotates through 180 degrees to be in the reversed position.

In such a way, the abutting section 32 abuts against the stopper 31, thus limiting the rotation angle of the monitor 3 to 180 degrees and also regulating the rotatable direction to one direction. Therefore, the helix angle of a wiring member 37 passing through the interior of the boss 11 and the bush 34 is also regulated 180 degrees or less, thus preventing twist breakage of the wiring.

Referring to FIG. 2A, FIG. 2B, and FIG. 3, the monitor opening and closing mechanism 200 of the biaxial hinge mechanism that achieves the opening and closing operation about the first axis X of the monitor 3 will next be discussed.

A pair of brackets 26 is provided in the monitor housing case 2 in a predetermined distance from each other. Meanwhile, the base 21 has a connection section 23 attached at each end thereof, and those connection sections 23 have their respective opening and closing shafts 24 provided on a straight line therein. The opening and closing shaft 24 has provided at the tip thereof an opening and closing leaf spring 25 attached therearound such that the spring is rotated integrally with the opening and closing shaft 24. Further, the bracket 26 is attached between the opening and closing shaft 24 and the opening and closing leaf spring 25. The opening and closing leaf spring 25 has an opening and closing engaging convexity 25a provided on the face of the one bracket 26 side thereof, and the opening and closing engaging convexity 25a is resiliently pressed against the bracket 26 by the elastic force obtained from the opening and closing leaf spring 25. Meanwhile, the other bracket 26 has opening and closing engaging concavities 28a, 28b, and 28c provided therein circumferentially in a predetermined distance. Those opening and closing engaging concavities 28a, 28b, and 28c are used for positioning the monitor 3 in the predetermined viewing positions, and the distance (angle) therebetween is properly determined.

Therefore, the monitor 3 can be rotated about the first axis X with respect to the bracket 26 using the opening and closing shaft 24, and moreover, the opening and closing leaf spring 25 is resiliently pressed against the bracket 26 by the opening and closing engaging convexity 25a. Thus, the monitor has suitable sliding resistance, and is opened and closed requiring a suitable torque.

Further, an opening and closing stopper 27 is formed on a fringe on the opening and closing engaging concavity 28a side of the bracket 26. The opening and closing stopper 27 is abutted against by the opening and closing leaf spring 25 attached at the tip of the opening and closing shaft 24 to thereby prevent the monitor 3 from being opened and closed beyond a predetermined amount.

It is to be noted that since the monitor opening and closing mechanism 200 includes two opening and closing shafts 24 parallel to the direction of the first shaft X, the mechanism has high vibration resistance, and does not easily chatter.

As discussed above, in accordance with the first embodiment, the monitor rotating mechanism 100 is arranged to include the sub-base 14 fixed to the base 21 of the monitor opening and closing mechanism 200; the cylindrical boss 11 of which one end is fixed to the top face 3c of the monitor 3, and of which the other end is supported rotatably about the second axis Y by the sub-base 14; and the bush 34 of which one end is fixed to the base 21 and which is inserted into the boss 11 to journal the boss 11. For this reason, if vibrations are transmitted to the biaxial hinge mechanism, the boss 11 is inclined with respect to the bush 34 only within the range of clearance K, thus enabling the leaf springs 13, 15 to be prevented from being flexed to chatter. As a result, the rigidity of the monitor rotating mechanism 100 is increased to prevent chatters by vibrations, which makes it possible to restrain swing of the monitor 3.

Further, the bush 34 is formed having a length extending halfway along the length of the boss 11. On that account, the bush 34 does not abut against the swelling section 35 of the boss 11, and the bush 34 can be completely inserted in the boss 11. Consequently, the rotational performance of the boss 11 to the bush 34 can be stabilized.

Furthermore, the groove 34a is provided along the outer peripheral face of the bush 34, and the O-ring 36 is inserted in the groove 34a. For this reason, if vibrations are transmitted to the biaxial hinge mechanism, the O-ring 36 acts as a buffer to enable the collision noise of the boss 11 with the bush 34 to be prevented from being generated.

Moreover, since the bush 34 is arranged to have a cylindrical shape, the wiring member 37 for connecting the monitor 3 with the main board can be passed through the bush 34.

In this context, in accordance with the first embodiment discussed above, it is arranged that the groove 34a to be inserted by the O-ring 36 be inserted is provided along the outer peripheral face of the bush 34; however, it may be arranged that the boss 11 have a groove provided along the inner peripheral face thereof to insert an O-ring in the groove.

Besides, fluid with a high viscosity such as silicone oil may be placed in the groove in place of the O-ring.

### INDUSTRIAL APPLICABILITY

As discussed above, the biaxial hinge mechanism according to the present invention, in order to prevent the chatter of the monitor rotating mechanism caused by vibrations and thereby restrain the monitor from swinging, is composed of the monitor opening and closing mechanism and the monitor rotating mechanism, and further the biaxial hinge mechanism is arranged such that the monitor rotating mechanism includes the sub-base, the cylindrical boss, and the bush for journaling the boss. Thus, the biaxial hinge mechanism is suitable for use in a biaxial hinge mechanism or the like used for opening and closing a monitor mounted on an automobile.

1. A biaxial hinge mechanism composed of a monitor opening and closing mechanism for allowing a monitor to open and close with respect to a first rotation center axis, and a monitor rotating mechanism for allowing the monitor which is rotated in the open direction with respect to the first rotation center axis to rotate with respect to a second rotation center axis orthogonal to the first rotation center axis,
wherein the monitor rotating mechanism includes:
a sub-base fixed to a base of the monitor opening and closing mechanism;
a cylindrical boss of which one end is fixed to the monitor, and of which the other end is supported rotatably about the second rotation center axis by the sub-base; and
a bush of which one end is fixed to the base of the monitor opening and closing mechanism and which is inserted into the boss from the other end side thereof to journal the boss.

2. The biaxial hinge mechanism according to claim 1, wherein the bush has a length extending partway along the length of the boss.

3. The biaxial hinge mechanism according to claim 1, wherein the bush has a groove provided along the outer peripheral face thereof or the boss has a groove provided along the inner peripheral face thereof, and the groove has a viscoelastic member inserted therein.

4. The biaxial hinge mechanism according to claim 1, wherein the bush has a cylindrical shape.
